(19) United States
(12) Patent Application Publication
(10) Pub. No.: US 2016/0126061 A1
(43) Pub. Date: May 5, 2016

(54) DRAWING APPARATUS AND DEVICE MANUFACTURING METHOD

(71) Applicant: CANON KABUSHIKI KAISHA, Tokyo (JP)

(72) Inventors: Masato Muraki, Inagi-shi (JP); Tomoyuki Morita, Utsunomiya-shi (JP)

(21) Appl. No.: 14/922,729

(22) Filed: Oct. 26, 2015

(30) Foreign Application Priority Data
Oct. 31, 2014 (JP) 2014-223352

(51) Int. Cl. H01J 37/317

(52) U.S. Cl. CPC H01J 37/3174

(57) ABSTRACT

In at least one embodiment, a control unit of a drawing apparatus determines a distance by which the drawing apparatus causes a stage to move in a direction parallel to an arranging direction of a plurality of shot regions, in such a manner that a plurality of shot regions includes a shot region including a drawing region in which drawing processing by at least one first charged particle beam is able to be performed and also drawing processing by at least one second charged particle beam is able to be performed. The control unit controls a drawing operation of a first charged particle optical system and a drawing operation of a second charged particle optical system to use either the at least one first charged particle beam or the at least one second charged particle beam to perform drawing processing in the shot region including the drawing region.

### BACKGROUND OF THE INVENTION

1. Field of the Invention

The present disclosure relates to a drawing apparatus and a device manufacturing method.

2. Description of the Related Art

It is conventionally known that a drawing apparatus can draw a desired pattern by causing a charged particle beam (e.g., an electron beam) to be directly incident on a wafer (i.e., a substrate) on which a resist (i.e., a photosensitive agent) is applied, without using a mask (i.e., an original), in a lithography process of a semiconductor device manufacturing method.

In general, drawing apparatuses are required to attain higher throughput. As discussed in Japanese Patent Application Laid-Open No. 11-150050, there is a multicolumn-type drawing apparatus that is capable of simultaneously performing drawing processing in a plurality of shot regions arranged on a substrate with a plurality of charged particle beams emitted from a plurality of charged particle optical systems.

FIGS. 6A and 6B are diagrams illustrating drawing processing that can be performed by a conventional drawing apparatus. More specifically, FIGS. 6A and 6B are diagrams illustrating drawing processing performed by a multicolumn-type drawing apparatus in a plurality of shot regions on a substrate.

A multicolumn MC illustrated in FIG. 6A includes six charged particle optical systems column_1 to column_6. A substrate W has a diameter of 300 mm. The six charged particle optical systems column_1 to column_6 are arrayed at pitches of 50.0 mm in a right and left direction on the paper surface.

When the drawing apparatus performs drawing processing, the drawing apparatus causes a stage holding the substrate W thereon to perform a scanning operation (move to perform scanning processing) in an upper direction on the paper surface in relation with the multicolumn MC, while causing the six charged particle optical systems column_1 to column_6 to perform drawing processing in stripe regions S1 to S6 thereof (hereinafter, referred to as “stripe drawing processing”). Subsequently, the drawing apparatus causes the substrate stage holding the substrate W thereon to move stepwise in the left direction on the paper surface, so that the six charged particle optical systems column_1 to column_6 can perform stripe drawing processing again. The drawing apparatus repeats the above-mentioned sequential operations. When the sum of step moving amounts reaches 50 mm (i.e., the arrangement pitch of the charged particle optical systems), the drawing apparatus completes drawing processing in all shot regions S on the substrate.

However, the size of each shot region S is not always the same and can be designed in an appropriate size depending on the type of each semiconductor device. Therefore, the pitch according to which the charged particle optical systems are arranged may not become equal to a multiple of the shot width SW (i.e., the width of the shot region S) in the right and left direction on the paper surface. For example, in a case where the shot width SW is 25 mm, two times the shot width SW becomes equal to the pitch according to which the charged particle optical systems are arranged. In a case where the shot width SW is 22 mm, two times the shot width SW becomes smaller than the pitch according to which the charged particle optical systems are arranged.

As illustrated in FIG. 6B, in the case where the shot width SW is 22 mm, thirteen shot regions S are arranged in the right and left direction on the paper surface. The shot regions S to be drawn by two charged particle optical systems that are positioned adjacent to each other are the third, fifth, seventh, tenth, and twelfth shot regions S from the left on the paper surface. In this case, if the mutually neighboring charged particle optical systems are different in drawing characteristics, there will be a difference in orientation (e.g., rotational error) between two drawing patterns drawn by the mutually neighboring charged particle optical systems.

Further, a connecting portion of two drawing patterns is a pattern in a state where one of the mutually neighboring charged particle optical systems starts drawing processing and also a pattern in a state where the other of the mutually neighboring charged particle optical systems terminates drawing processing. Therefore, in a case where the position of the substrate W is temporally unstable in relation with two charged particle optical systems, two drawing patterns may overlap with each other or split at the connecting portion thereof. In other words, the drawing apparatus cannot draw a desired pattern as designed at the connecting portion of two drawing patterns to be drawn by the mutually neighboring charged particle optical systems.

### SUMMARY OF THE INVENTION

The present disclosure is directed to a drawing apparatus capable of drawing a desired pattern in a plurality of shot regions on a substrate with a plurality of charged particle optical systems even in a case where a connecting portion of drawing patterns drawn by mutually neighboring charged particle optical systems is present in a shot region.

According to an aspect of the present disclosure, at least one embodiment of a drawing apparatus performs drawing processing in a plurality of shot regions on a substrate with a plurality of charged particle beams. The drawing apparatus includes a stage configured to hold the substrate thereon and move when the drawing apparatus performs drawing processing, a first charged particle optical system configured to irradiate the substrate with at least one first charged particle beam of the plurality of charged particle beams, a second charged particle optical system configured to irradiate the substrate with at least one second charged particle beam of the plurality of charged particle beams, and a control unit configured to control a moving operation of the stage, a drawing operation of the first charged particle optical system, and a drawing operation of the second charged particle optical system, wherein the first charged particle optical system and the second charged particle optical system are arranged adjacent to each other, wherein the plurality of shot regions is arranged in an arranging direction parallel to an arranging direction of the first charged particle optical system and the second charged particle optical system on the substrate, wherein the stage moves in a direction parallel to the arranging direction of the plurality of shot regions, wherein the control unit is configured to determine a distance by which the drawing apparatus causes the stage to move in the direction parallel to the arranging direction of the plurality of shot regions, in such a manner that the plurality of shot regions includes a shot region including a drawing region in which drawing processing by the at least one first charged particle beam is able to be performed and also drawing processing by the at least one second charged particle beam is able to be performed, and wherein the control unit is configured to control the drawing operation of the first charged particle optical system and the drawing operation of the second charged particle optical system in such a way as to use either the at least one first charged particle beam or the at least one second charged particle beam to perform drawing processing in the shot region including the drawing region in which the drawing processing by the at least one first charged particle beam is able to be performed and also the drawing processing by the at least one second charged particle beam is able to be performed.

According to other aspects of the present disclosure, one or more additional drawing apparatuses and one or more device manufacturing methods are discussed herein. Further features of the present disclosure will become apparent from the following description of exemplary embodiments with reference to the attached drawings.

### BRIEF DESCRIPTION OF THE DRAWINGS

FIG. 1 is a diagram illustrating a configuration of a drawing apparatus according to the present disclosure.

FIG. 2 is a diagram illustrating a configuration of a charged particle optical system according to the present disclosure.

FIGS. 3A, 3B, and 3C are diagrams illustrating drawing processing that is performed by the drawing apparatus according to the present disclosure.

FIGS. 4A and 4B are diagrams illustrating drawing processing that is performed by the drawing apparatus according to the present disclosure.

FIG. 5 is a diagram illustrating drawing processing that is performed by the drawing apparatus according to the present disclosure.

FIGS. 6A and 6B are diagrams illustrating drawing processing that is performed by a conventional drawing apparatus.

### DESCRIPTION OF THE EMBODIMENTS

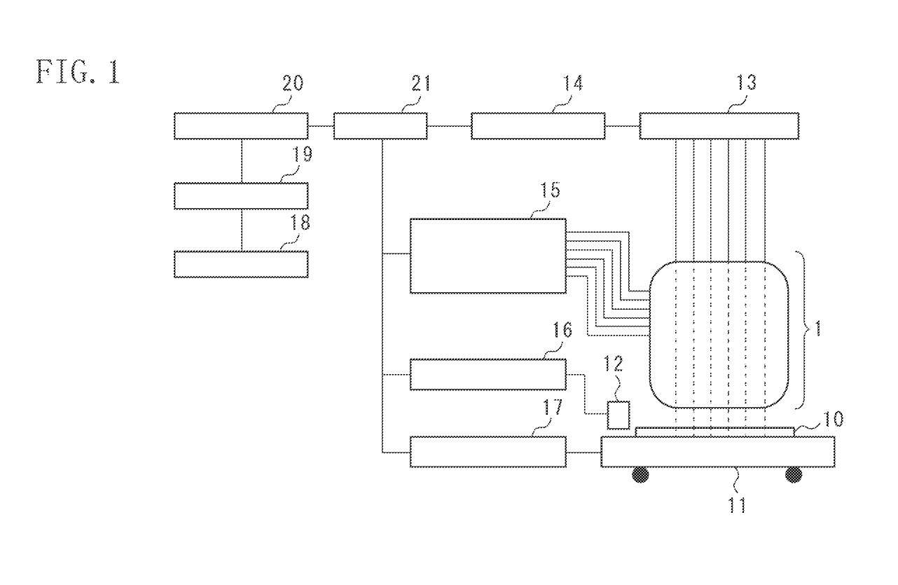

FIG. 1 is a diagram illustrating a configuration of a drawing apparatus. The drawing apparatus is a lithography apparatus that forms a pattern on a substrate with a plurality of charged particle beams emitted from a plurality of charged particle optical systems, respectively. For example, the charged particle beams are electron beams or ion beams.

The drawing apparatus illustrated in FIG. 1 includes a multicolumn 1 including a plurality of charged particle optical systems (e.g., six charged particle optical systems according to the present exemplary embodiment), a substrate stage 11, a position detecting system 12, a blanking control unit 13, a data processing unit 14, a deflector control unit 15, a position detection processing unit 16, a stage control unit 17, a design data storing unit 18, a data conversion unit 19, an intermediate data storing unit 20, and a main control unit 21. A plurality of charged particle optical systems 100 included in the multicolumn 1 can irradiate a substrate 10 held on the substrate stage 11 with a plurality of charged particle beams.

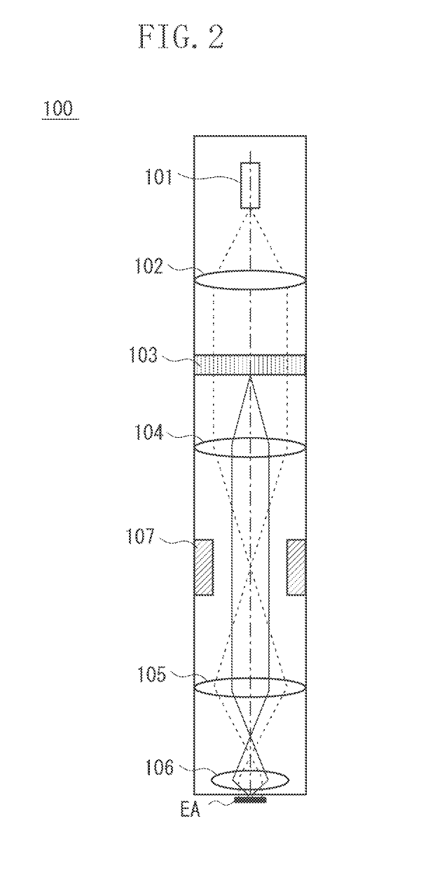

FIG. 2 is a diagram illustrating a configuration of each of the plurality of charged particle optical systems 100.

The charged particle optical system 100 includes a charged particle source 101, a collimator lens 102, a blanking aperture array 103, an electrostatic lens 104, an electromagnetic lens 105, an objective lens 106, and a deflector 107.

For example, the charged particle source 101 is a thermionic-type charged particle source that includes a charged particle beam emission material, such as LaB₆BaO/W, or the like (i.e., dispenser cathode). The collimator lens 102 is an electrostatic lens that converges charged particle beams (electron beams according to the present exemplary embodiment) under application of an electric field. The collimator lens 102 shapes the charged particle beams emitted from the charged particle source 101 into charged particle beams that are substantially parallel to each other.

The blanking aperture array 103 includes a plurality of apertures (not illustrated) arrayed in a two-dimensional pattern along a plane perpendicular to an optical axis of the charged particle optical system 100. The substantially parallel charged particle beams from the collimator lens 102 is split into a plurality of charged particle beams through the plurality of apertures. Further, the blanking aperture array 103 includes an electrostatic type blanking deflector (not illustrated) that is capable of driving the plurality of charged particle beams independently. The blanking aperture array 103 switches irradiation/non-irradiation (ON/OFF) of the substrate 10 for each of the plurality of charged particle beams.

The electrostatic lens 104 and the electromagnetic lens 105 cooperatively form intermediate images of the plurality of apertures of the blanking aperture array 103. The objective lens 106 is an electromagnetic lens, which projects (or reimages) the intermediate images of the plurality of apertures on the substrate 10. The deflector 107 deflects the plurality of charged particle beams from the blanking aperture array 103 in a batch manner in a predetermined direction and can change the position of a drawing region EA defined by the plurality of charged particle beams.

Referring back to FIG. 1, the substrate stage 11 moves while holding the substrate 10 thereon. For example, the substrate stage 11 includes an X-Y stage and an electrostatic chuck. The X-Y stage is movable along an X-Y plane (i.e., a horizontal plane) perpendicular to the optical axis of the charged particle optical system 100 (i.e., a vertical direction). The electrostatic chuck pulls and holds the substrate 10. Further, a detector (not illustrated) for detecting the position of a charged particle beam is disposed on the substrate stage 11. The detector has an aperture and a light receiving portion. When a charged particle beam reaches the light receiving portion via the aperture, the detector converts the charged particle beam into an electric signal to detect the position of the charged particle beam.

The position detecting system 12 includes an irradiation system that irradiates a mark (e.g., an alignment mark) formed on the substrate 10 with light having a wavelength to which the resist is not sensitive and an image sensor that captures an image of light reflected by the mark, to detect the position of the mark.

The blanking control unit 13 controls the blanking aperture array 103 independently for each of the plurality of charged particle optical systems 100 included in the multicolumn 1. The data processing unit 14 includes a buffer memory and a data processing circuit. The data processing unit 14 can generate control data for each of the plurality of charged particle optical systems 100. The deflector control unit 15 can control the deflector 107 independently for each of the plurality of charged particle optical systems 100.

The position detection processing unit 16 calculates and identifies an actual position (e.g., coordinate values) of a pattern formed on the substrate 10 and the presence of any deformation occurring on the pattern, based on a detection result (i.e., a detected mark position) obtained by the position detecting system 12. The stage control unit 17 controls the positioning of the substrate stage 11 in cooperation with a laser interferometer (not illustrated) that measures the position of the substrate stage 11.

The design data storing unit 18 is a memory for storing graphic design data corresponding to a pattern to be drawn on the substrate 10. The data conversion unit 19 splits the graphic design data stored in the design data storing unit 18 into a plurality of group data that correspond to respective stripe regions to be drawn by the charged particle optical system 100 and converts the graphic design data into intermediate graphic data, so that the drawing apparatus can easily perform drawing processing. The intermediate data storing unit 20 is a memory for storing the intermediate graphic data.

The main control unit 21 includes a central processing unit (CPU) and at least one memory to control various operations of the drawing apparatus (including the moving operation of the substrate stage 11 and the drawing operation of the charged particle optical system 100). The main control unit 21 transfers intermediate graphic data generated from graphic design data corresponding to a pattern to be drawn on the substrate 10 to the buffer memory in the data processing unit 14 and controls various operations to be performed by the drawing apparatus via each unit of the above-mentioned drawing apparatus. Further, the main control unit 21 may be configured to have functions comparable to those of the blanking control unit 13, the data processing unit 14, the deflector control unit 15, the position detection processing unit 16, the stage control unit 17, the design data storing unit 18, the data conversion unit 19, and the intermediate data storing unit 20, instead of providing these functional units independently in the drawing apparatus.

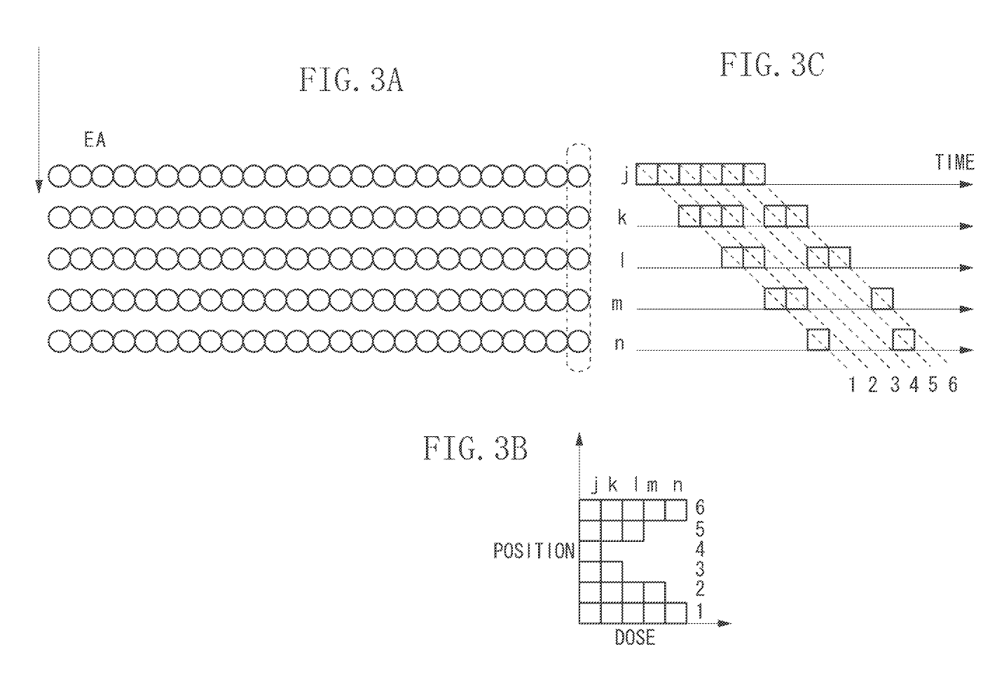

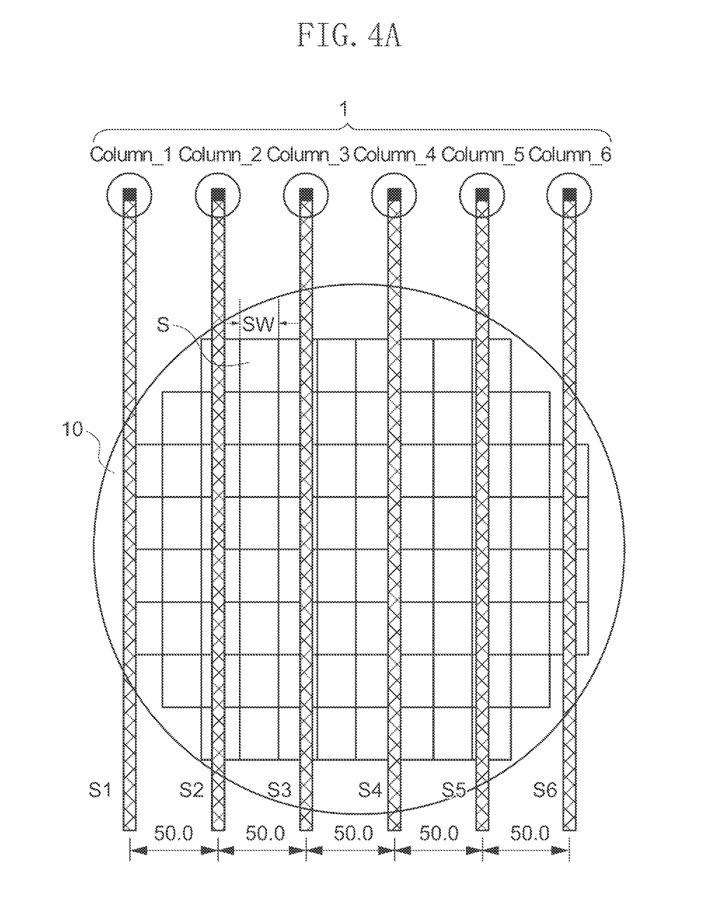

FIGS. 3A to 3C are diagrams illustrating drawing processing that is performed by the drawing apparatus.

FIG. 3A is a diagram illustrating an arrangement of a plurality of charged particle beams, which are emitted from the plurality of charged particle optical systems 100 in such a way as to define the drawing region EA on the substrate 10. In the present exemplary embodiment, the plurality of charged particle beams includes a matrix of 5 rows and 25 columns, in which the pitch of charged particle beams in the rows is two times of the pitch of charged particle beams in the columns.

The charged particle optical system 100 irradiates the substrate 10 with a plurality of charged particle beams based on the same clock signal. The substrate stage 11 moves in the lower direction on the paper surface indicated by an arrow, in relation with the charged particle optical system 100, to perform a scanning operation at a speed corresponding to the column pitch per clock. The main control unit 21 determines whether to irradiate a predetermined position of the substrate 10 by independently controlling ON/OFF of the plurality of charged particle beams, while causing the substrate stage 11 holding the substrate 10 thereon to perform a scanning operation.

It is now assumed that the drawing apparatus performs drawing processing with the charged particle beams arranged to form the matrix of 5 rows×25 columns illustrated in FIG. 3A, a relationship between “POSITION” of position_1 to position_6 arranged at pitches similar to the column pitch on the substrate 10 in the upper-and-lower direction on the paper surface and “DOSE” of irradiation amount (exposure amount) of the charged particle beams for rows j to n emitted for respective positions 1 to 6 becomes a relationship illustrated in FIG. 3B.

In this case, the substrate stage 11 moves by an amount equivalent to one row pitch in response to two unit clocks. Therefore, it is feasible to obtain the relationship illustrated in FIG. 3B by setting ON/OFF of the charged particle beams for the rows j to n per unit clock as illustrated in FIG. 3C. Dotted lines illustrated in FIG. 3C correspond to ON/OFF (a region indicated by a mark having square shape is ON and a non-marked region is OFF) signals of the charged particle beams for the rows j to n emitted for respective position_1 to position_6.

The drawing apparatus starts drawing processing after starting the ON/OFF control of the charged particle beams for the row j at the position Position_1. The drawing apparatus terminates the drawing processing upon completing the ON/OFF control of the charged particle beams for the row n at the position_6. FIG. 3B illustrates the sum of irradiation amounts of the charged particle beams for the rows j to n emitted for respective positions (position_1 to position_6). The drawing apparatus employs the above-mentioned gradation in performing the drawing processing so that a desired pattern can be drawn.

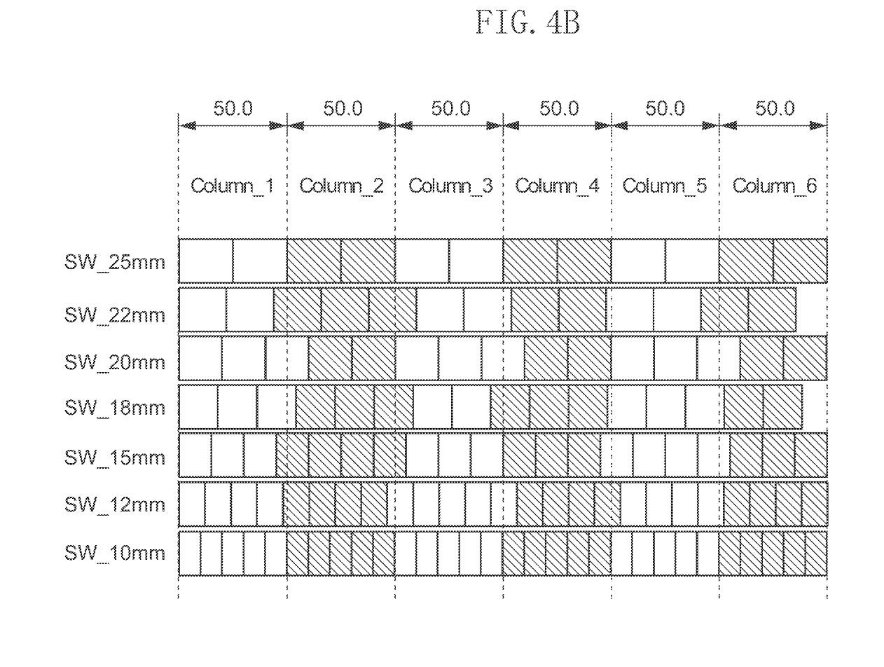

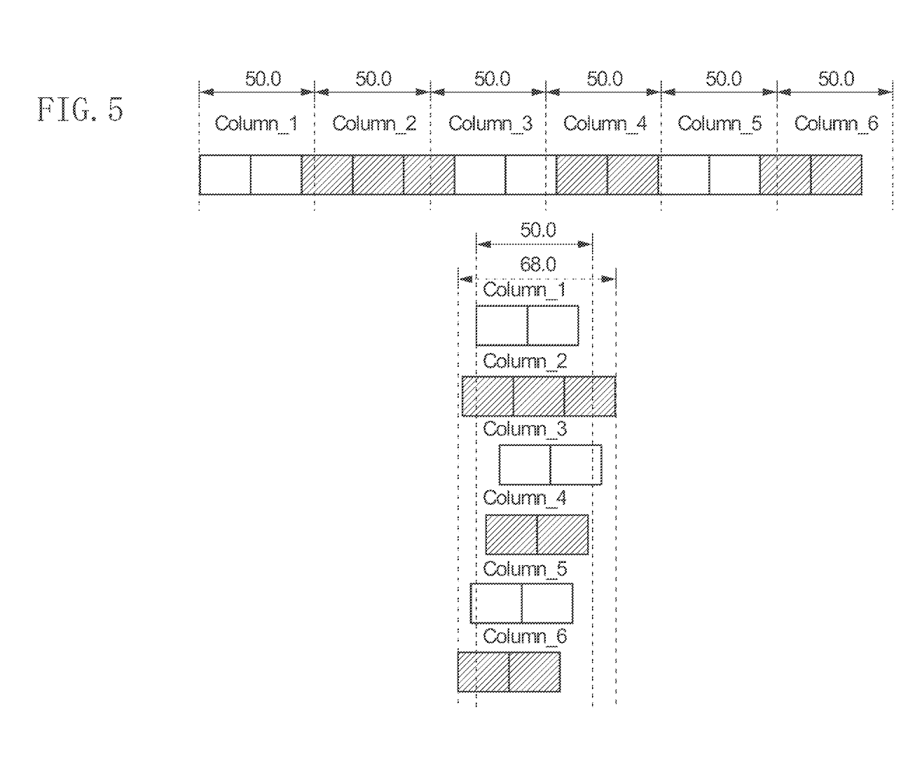

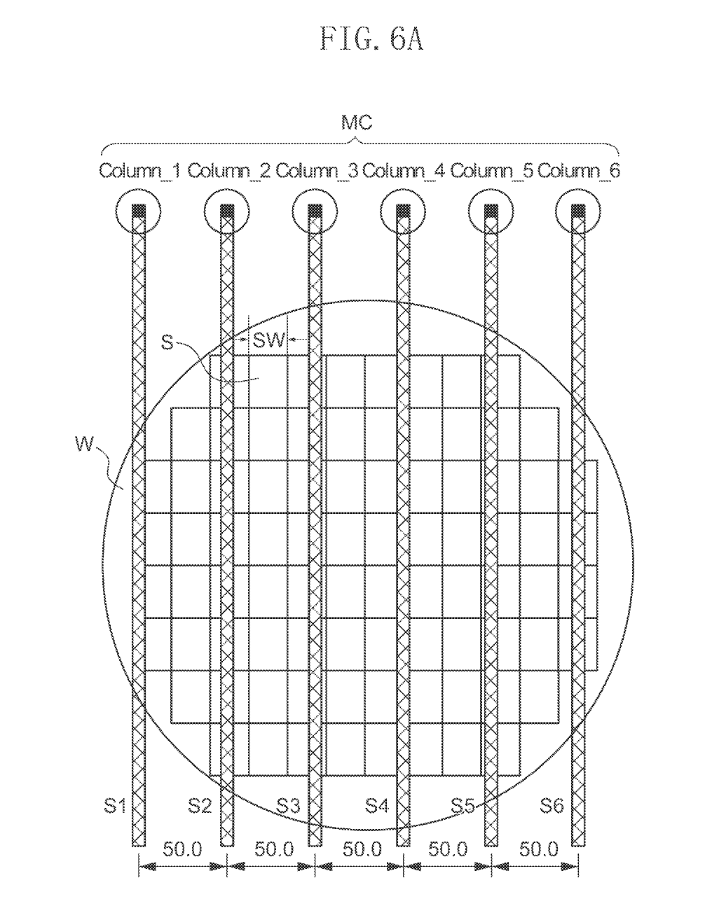

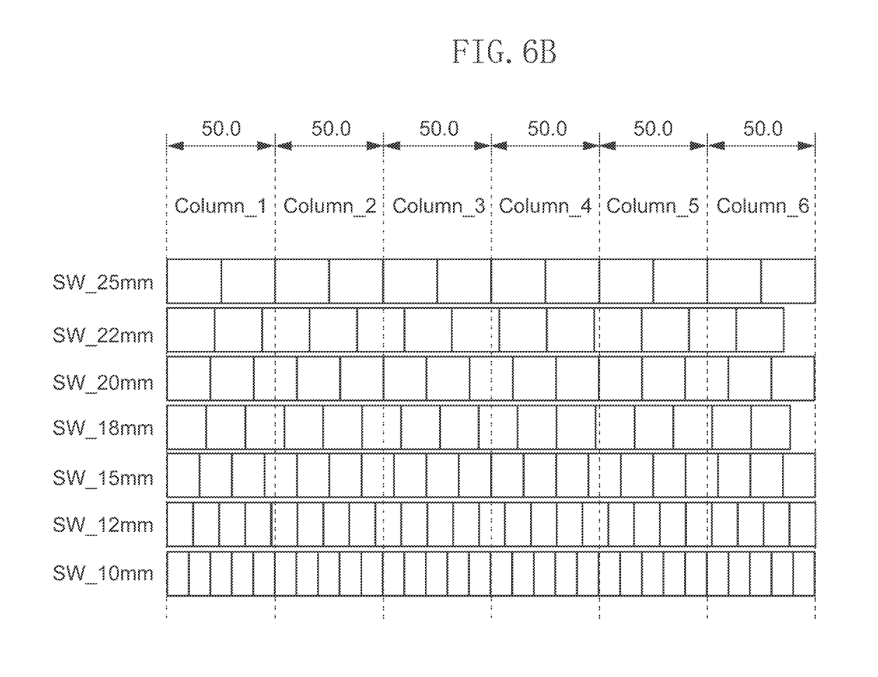

FIGS. 4A and 4B and FIG. 5 are diagrams illustrating drawing processing that is performed by the drawing apparatus.

FIG. 4A illustrates a drawing of patterns in a plurality of shot regions S on the substrate 10, which is performed by six charged particle optical systems column_1 to column_6 that are included in the multicolumn 1.

The substrate 10 has a diameter of 300 mm. The six charged particle optical systems column_1 to column_6 are arranged at pitches of 50.0 mm in the right and left direction on the paper surface.

In performing drawing processing, the drawing apparatus causes the substrate stage 11 holding the substrate 10 thereon in such a way as to perform a scanning operation (i.e., move to perform scanning) in relation with the multicolumn 1, in the upper direction on the paper surface, so that the six charged particle optical systems column_1 to column_6 perform stripe drawing processing in respective stripe regions S1 to S6. Subsequently, the drawing apparatus causes the substrate stage 11 to move together with the substrate 10 held thereon stepwise in the left direction on the paper surface, so that the six charged particle optical systems column_1 to column_6 can perform stripe drawing processing again. The drawing apparatus repeats the above-mentioned sequential operations to perform drawing processing in all shot regions S on the substrate.

In the present exemplary embodiment, even if the shot width of the shot region is changed, the drawing apparatus controls the drawing operations of a respective plurality of charged particle optical systems and controls the moving operation of the substrate stage so that the drawing processing in all shot regions is performed by only one of the plurality of charged particle optical systems.

FIG. 4B illustrates examples of a plurality of shot regions S corresponding to different values of the shot width SW, which are arranged in the right and left direction on the paper surface. The drawing apparatus uses the charged particle optical systems column_1, column_3, and column_5 to perform drawing processing in non-hatched shot regions S. Further, the drawing apparatus uses the charged particle optical systems column_2, column_4, and column_6 to perform drawing processing in hatched shot regions S. In FIG. 4B, vertical dotted lines indicate borderlines of the drawing regions of respective charged particle optical systems. For example, in the case where the shot width SW is 22 mm, the shot regions S each including a borderline are the third, fifth, seventh, tenth, and twelfth shot regions S from the left of the thirteen shot regions arranged in the right and left direction on the paper surface. The remaining shot regions S include no borderline.

It is conventionally known to use each corresponding charged particle optical system to perform drawing processing in each shot region S including no borderline and use two charged particle optical systems that are mutually adjacent to each other to cooperatively perform drawing processing in each shot region S including a borderline.

The drawing apparatus according to the present exemplary embodiment is characterized by using only one of two neighboring charged particle optical systems in performing drawing processing in each shot region S including a borderline, although the drawing apparatus according to the present exemplary embodiment is not different from the conventional drawing apparatus in using a corresponding charged particle optical system to perform drawing processing in each shot region S having no borderline.

In particular, the main control unit 21 selects one of two charged particle optical systems based on largeness of a drawing region that can be drawn by the selected charged particle optical system in the shot region S including a borderline. For example, in a case where the shot width SW is 22 mm, either the charged particle optical system column_1 or the charged particle optical system column_2 is selectable to perform drawing processing in the third shot region S from the left. In this case, the main control unit 21 according to the present exemplary embodiment selects the charged particle optical system column_2 because of largeness in the drawing region in the third shot region S. The drawing apparatus according to the present exemplary embodiment performs drawing processing in the third shot region S by using only the selected charged particle optical system column_2.

Therefore, even in a case where the two charged particle optical systems column_1 and column_2 are different in drawing characteristics, the drawing apparatus can draw a desired pattern in each shot region S including a borderline.

A method will be described in detail below with reference to FIG. 5, in which the main control unit 21 selects a charged particle optical system to be used in performing drawing processing in a shot region S including a borderline and controls a moving operation of the substrate stage 11 when the drawing apparatus performs the drawing processing with a selected charged particle beam.

An upper part of FIG. 5 illustrates a plurality of shot regions S arranged in the right and left direction on the paper surface in relation with borderlines between respective drawing regions of six charged particle optical systems column_1 to column_6, in the case where the shot width SW is 22 mm. A lower part of FIG. 5 illustrates the shot regions S rearranged from the arrangement illustrated in the upper part of FIG. 5 with reference to the arrangement pitch of the charged particle optical systems (=50.0 mm).

As illustrated in the lower part of FIG. 5, to enable only one of the six charged particle optical systems column_1 to column_6 to perform drawing processing in thirteen shot regions S, the moving distance (stroke) of the substrate stage 11 is set to be 68.0 mm that is longer than the arrangement pitch of the charged particle optical systems (=50.0 mm) so that the drawing regions of two neighboring charged particle optical systems can be overlapped with each other. In particular, when the drawing apparatus starts the drawing processing, the main control unit 21 controls the moving operation of the substrate stage 11 in such a way as to cause the charged particle optical system column_6 to perform drawing processing at a portion including a left edge of the twelfth shot region S from the left. When the drawing apparatus terminates the drawing processing, the main control unit 21 controls the moving operation of the substrate stage 11 in such a way as to cause the charged particle optical system column_2 to perform drawing processing at a portion including a right edge of the fifth shot region S from the left.

In this case, for example, the third shot region S from the left includes a drawing region in which drawing by the charged particle optical system column_2 is feasible and drawing by the charged particle optical system column_1 is unfeasible. Therefore, the main control unit 21 controls the drawing operations of two charged particle optical systems column_1 and column_2 in such a way as to cause only the charged particle optical system column_2 to perform drawing processing in the third shot region S from the left. Further, the main control unit 21 determines the stroke of the substrate stage 11 in such a way as to minimize a portion where drawing regions of respective charged particle optical systems are overlapped with each other, from the point of view of throughput.

The drawing apparatus according to the present exemplary embodiment can draw a desired pattern on a substrate with a plurality of charged particle optical systems, even in a case where the shot region size has been changed.

The drawing apparatus according to the present exemplary embodiment is advantageous in simultaneously drawing desired patterns in a plurality of shot regions with a plurality of charged particle optical systems. For example, the drawing apparatus according to the present exemplary embodiment can be used to manufacture a micro device having a semiconductor device or a fine structure. In such a case, a device manufacturing method according to an exemplary embodiment of the present disclosure includes a process for forming a desired latent image pattern on a photosensitive agent applied to a substrate with a drawing apparatus (i.e., a process for performing drawing on a substrate) and a process for developing the substrate on which the latent image pattern has been formed through the above-mentioned process (i.e., a process for developing the drawn substrate). The above-mentioned device manufacturing method can include other conventionally known processes (e.g., oxidation, film formation, evaporation, doping, flattening, etching, resist stripping, dicing, bonding, and packaging). The device manufacturing method according to the present exemplary embodiment is advantageous in at least one of performance, quality, productivity, and production cost of each device, compared to the conventional method.

In at least one embodiment of the present disclosure, a drawing apparatus may be provided that is capable of drawing a desired pattern on a substrate with a plurality of charged particle optical systems, for example, even in a case where the shot region size has been changed.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2014-223352, filed Oct. 31, 2014, which is hereby incorporated by reference herein in its entirety.

What is claimed is:

1. A drawing apparatus that performs drawing processing in a plurality of shot regions on a substrate with a plurality of charged particle beams, the drawing apparatus comprising:
a stage configured to hold the substrate thereon and move when the drawing apparatus performs drawing processing;
a first charged particle optical system configured to irradiate the substrate with at least one first charged particle beam of the plurality of charged particle beams;
a second charged particle optical system configured to irradiate the substrate with at least one second charged particle beam of the plurality of charged particle beams; and
a control unit configured to control a moving operation of the stage, a drawing operation of the first charged particle optical system, and a drawing operation of the second charged particle optical system,
wherein the first charged particle optical system and the second charged particle optical system are arranged adjacent to each other,
wherein the plurality of shot regions is arranged in an arranging direction parallel to an arranging direction of the first charged particle optical system and the second charged particle optical system on the substrate,
wherein the stage moves in a direction parallel to the arranging direction of the plurality of shot regions,
wherein the control unit is configured to determine a distance by which the drawing apparatus causes the stage to move in the direction parallel to the arranging direction of the plurality of shot regions, in such a manner that the plurality of shot regions includes a shot region including a drawing region in which drawing processing by the at least one first charged particle beam is able to be performed and also drawing processing by the at least one second charged particle beam is able to be performed, and
wherein the control unit is configured to control the drawing operation of the first charged particle optical system and the drawing operation of the second charged particle optical system in such a way as to use either the at least one first charged particle beam or the at least one second charged particle beam to perform drawing processing in the shot region including the drawing region in which the drawing processing by the at least one first charged particle beam is able to be performed and also the drawing processing by the at least one second charged particle beam is able to be performed.

2. The drawing apparatus according to claim 1, wherein the distance by which the drawing apparatus causes the stage to move is longer than an arrangement pitch of the first charged particle optical system and the second charged particle optical system.

3. The drawing apparatus according to claim 1, wherein the shot region including the drawing region in which the drawing processing by the at least one first charged particle beam is able to be performed and also the drawing processing by the at least one second charged particle beam is able to be performed further includes a drawing region in which drawing is feasible by one of the at least one first charged particle beam and the at least one second charged particle beam and also drawing is unfeasible by the other of the at least one first charged particle beam and the at least one second charged particle beam.

4. The drawing apparatus according to claim 1, wherein a second plurality of shot regions, other than the plurality of shot regions, is arranged on the substrate in the direction parallel to the arranging direction of the plurality of shot regions, and
when the drawing apparatus performs drawing processing, the stage moves to perform scanning in a direction perpendicular to the arranging direction of the plurality of shot regions and then moves stepwise in the direction parallel to the arranging direction of the plurality of shot regions.

5. A drawing apparatus that performs drawing processing in a plurality of shot regions on a substrate with a plurality of charged particle beams, the drawing apparatus comprising:
a stage configured to hold the substrate thereon and move when the drawing apparatus performs drawing processing;
a first charged particle optical system configured to irradiate the substrate with at least one first charged particle beam of the plurality of charged particle beams;
a second charged particle optical system configured to irradiate the substrate with at least one second charged particle beam of the plurality of charged particle beams;
a third charged particle optical system configured to irradiate the substrate with at least one third charged particle beam of the plurality of charged particle beams;
a fourth charged particle optical system configured to irradiate the substrate with at least one fourth charged particle beam of the plurality of charged particle beams; and
a control unit configured to control a moving operation of the stage, a drawing operation of the first charged particle optical system, a drawing operation of the second charged particle optical system, a drawing operation of the third charged particle optical system, and a drawing operation of the fourth charged particle optical system,
wherein the first charged particle optical system and the second charged particle optical system are arranged adjacent to each other, and the third charged particle optical system and the fourth charged particle optical system are arranged adjacent to each other in an arranging direction of the first charged particle optical system and the second charged particle optical system,
wherein the plurality of shot regions is arranged in an arranging direction parallel to the arranging direction of the first charged particle optical system and the second charged particle optical system on the substrate,
wherein the stage moves in a direction parallel to the arranging direction of the plurality of shot regions, and
wherein the control unit is configured to determine a distance by which the drawing apparatus causes the stage to move in the direction parallel to the arranging direction of the plurality of shot regions, in such a manner that the plurality of shot regions includes a first shot region including a drawing region in which drawing processing by the at least one first charged particle beam is able to be performed and also drawing processing by the at least one second charged particle beam is able to be performed and a second shot region including a drawing region in which drawing processing by the at least one third charged particle beam is able to be performed and also drawing processing by the at least one fourth charged particle beam is able to be performed,
wherein the control unit is configured to control the drawing operation of the first charged particle optical system, the drawing operation of the second charged particle optical system, the drawing operation of the third charged particle optical system, and the drawing operation of the fourth charged particle optical system in such a way as to use the at least one first charged particle beam to perform drawing processing in the first shot region and use the at least one fourth charged particle beam to perform drawing processing in the second shot region, and
wherein the control unit is configured to cause the stage to move until the drawing apparatus terminates the drawing processing in the first shot region after starting the drawing processing in the second shot region.

6. A device manufacturing method, comprising:
causing the drawing apparatus according to claim 1 to perform drawing processing on a substrate; and
developing the substrate on which the drawing processing has been performed.
